(19) United States
(12) Patent Application Publication
(10) Pub. No.: US 2013/0147313 A1
(43) Pub. Date: Jun. 13, 2013

(54) Method for producing a MEMS apparatus with a high aspect ratio, and converter and capacitor

(71) Applicant: Matthias Sachse, Wiener Neustadt (AT)

(72) Inventor: Matthias Sachse, Wiener Neustadt (AT)

(73) Assignees: Tecnet Equity NO Technologiebeteiligungs-Invest GmbH, St. Polten (AT); Osterreichische Akadernie der Wissenschaften (OAW), Wien (AT)

(21) Appl. No.: 13/816,556

(22) PCT Filed: Aug. 12, 2011
(86) PCT No.: PCT/EP2011/063974

§ 371 Date: Feb. 12, 2013

(30) Foreign Application Priority Data
Aug. 12, 2010 (AT) GM 507/2010

(51) Int. Cl. B81C 1/00; H02N 1/00

(52) U.S. Cl. CPC B81C 1/00619; H02N 1/008
USPC 310/300; 438/52

(57) ABSTRACT

The invention presents a method for producing microstructured apparatuses for microelectromechanical systems (MEMS). In order to increase the maximum aspect ratio conditioned by physical or chemical microstructuring methods, it is proposed to design flat elements of the apparatus, which are structured such that they are movable relative to one another, to be laterally changeable from a first reference position relative to one another (structuring position) to a second reference position (operating position) in a permanent or irreversible manner. As a result, higher trench capacitances can be formed between structured wall sections. The reference position can be changed by means of integrated drives or by supplying energy from the outside and said change is effected in a direction which is substantially different from the measuring direction. In addition to mechanical work and energy from electrical or magnetic fields, heat can be used to shift location in drives as a result of the action of force on an element or induced changes in length. This method makes it possible to produce highly sensitive sensors for very small excitation signals or to produce economical actuators with an extremely high level of efficiency in the form of low-attenuation, area-optimized, highly capacitive converters, as well as variable vertical capacitors with a high capacitance.

The present invention concerns a method for producing microelectromechanical structures (acronym: MEMS) with high aspect ratio.

Moreover, the present invention concerns converters or capacitors with micromechanical structures that comprise electrodes that are separated from each other by grooves.

The actual converter function of converters configured in this way is preferably achieved by means of interaction of movable and electrically differently charged oppositely positioned surfaces, on the one hand, and the electrical potential difference that is being applied or present at its supply lines, on the other hand.

In particular, the invention concerns MEMS sensors, in particular for one or several of the measured values, such as travel distance, vibration, acceleration, speed, rotary speed, force, pressure or torque, that can be determined by the effect of a change in travel.

The architecture according to the invention of this sensor enables in this context a movement of at least one electrode from a production position into an operative rest position closer to another electrode. The operative rest position of two electrodes that are positioned relative to each other in accordance with the method according to the invention is characterized by an increased aspect ratio.

In the same way, actuators (transducers) with such an architecture are encompassed such as preferably micromotors (for linear or rotating movement, or for vibration generation), micropumps, drives (for example, for light modulators via mirror arrays)), vibration transducers, switches or relays.

Special comb structures as they are used in already known comb actuators (English: comb drives) are suitable for use of this invention.

However, applications without converter function can also be encompassed by the present invention. For example, the nominal position determines the target capacitance of an integral or discrete capacitor that is produced in this way. Microstructured trimming capacitors or those with fixedly adjustable capacitance are further applications of the instant invention.

The capacitor that is produced in this way can also serve in circuits as converter element in frequency-to-voltage converters, voltage-to-frequency converters or analog-digital converters or for measuring time. Moreover, such elements can serve for compensation of errors as a result of temperature changes.

The invention is based on a MEMS method according to the prior art and a MEMS converter of the aforementioned kind as it is disclosed in many publications concerning sensors for measuring or actuators for generating travel changes, displacements or accelerations, oscillations or vibrations in different directions, but also angular changes or angular accelerations about different axes.

In sensors, there is an electrical target signal in the form of an electric potential change or an electrical current change. This signal can subsequently be amplified by means of transistor circuits and can be evaluated by means of analog-digital circuits and is a measure for the mechanical or thermal input. The mechanical input can be the result of the force of gravity or another acceleration, for example, shaking, but can also be vibration excitation acting on a membrane or a pressure.

In case of micro-actuators, a mechanical actuating variable or excitation or a thermally induced change in length is the result of an electrical signal change at the electrodes. This actuating variable can be periodically activated as is the case of linear or circular oscillators or even in case of micromotors. Accordingly, new inertial systems can be formed whose vibration axes, vibration planes or rotor planes, relative to outer force introduction, generate an inertia that, in turn, is utilized in sensing. The actuation force is usually the result of the effect of an electrical or, more rarely, of a magnetic field or the result of a shape-changing temperature change of an element as a result of thermal dissipation loss in an actuating member through which current flows or as a result of an electrostrictive or magnetostrictive effect.

As restoring forces, usually spring forces are utilized wherein the work for pretensioning micro bending beams or micro spiral springs must be introduced additionally by means of the actuation forces along the adjustment travel. In addition, membranes as energy stores are used for restoring forces.

The Coriolis force effects deflections of the vibrating or rotating masses in a direction perpendicular to the vibration or rotation direction when a change of the vibration axis direction or the position of the vibration or rotation plane is imprinted from the exterior onto the inertial system. These deflections are, in turn, detected by sensors in order to measure incline, rotary speed or angular accelerations.

When the axes of these new inertial systems are changed from the exterior in their direction, precession forces are formed that are decoupled mechanically by means of the support devices of the vibration systems and can cause positional changes, for example, of the bending beams, that can be detected by sensors. When detecting precession forces, the frequency of the actuator vibration or the rotary speed of the actuator only indirectly affects the magnitude of the amplitude of the measurement while in case of detection of the Coriolis force in vibration systems the measuring signal is modulated with the vibration frequency.

Microelectronic analog circuits or mixed analog-digital microelectronic circuits have often capacitor structures that, as a result of very small capacitance per surface area of typically 1.75 fF/μm² or less, have a significant surface area demand. The capacitance of these capacitor structures is, for example, formed by two metal layers that are insulated relative to each other or by two insulated polysilicon layers or by a diffusion layer of doped silicon and an insulated polysilicon layer. In this connection, silicon dioxide is used as an insulator. Aluminum is applied as the metal layer.

Component structures in micromechanics can be produced by the deep etching methods, for example, the reactive silicon ion deep etching (Bosch process) with relatively high aspect ratio. The aspect ratio is understood as the ratio of depth of a produced groove or a recess relative to the lateral dimension.

A known deep structuring method in the form of a plasma etching process is disclosed, for example, in DE 42 41 045. With the described trench method already grooves with a minimum groove width of 1 μm can be produced and opened. As in all plasma etching processes, the etching rate, i.e., the speed of material removal, depends on the structure spacings. In case of narrow etch openings the etching rate is significantly smaller than the etching rate that can be achieved in case of wide etch openings. The etching rate is substantially independent of the structure spacings only at spacings above approximately 10 μm.

In summarizing the above, it can be stated that with the methods known up to now spacings of less than 1 μm cannot be reproducibly manufactured or at least not reliably manufactured and up to now, because of the required processing precision, have not been considered to be feasible.

In converters with micromechanical structures that comprise electrodes which are separated from each other by grooves, large electrode spacings have a minimal electrical sensitivity. Low sensitivity means a greater size of the structures because more electrode surface is required, or larger and also more noise-reduced amplifiers must be employed in order to achieve the required converter performance. However: the wider the structures are separated from each other, the deeper and faster structuring can be done.

In DE 101 05 167 it is proposed that for enlarging the aspect ratio of the grooves at least section-wise on the sidewalls of the grooves a further layer is deposited so that smaller groove widths are obtained. In JP 2009 190 150 an oxide film is formed by thermal oxidation which reduces the groove width. These methods require additional manufacturing steps and therefore higher production times and production costs as well as precise monitoring of the process steps, and in principle, higher defect rates are observed as a result of the process-related limits.

DE 101 45 721 propose an electrode structure that is designed vertically relative to the substrate plane which enables a mechanical positioning of a separated fingered and moveable electrode between two further electrodes so that the finger structure can be guided from a non-immersed position into an immersed position in the matching counter structure with recesses for the finger structures. In this way, electrode spacings of 100 nm are possible but the expenditure for structuring and joining is however very high as a result of the vertical configuration of three layered components. Moreover, this requires three times the material surface.

U.S. Pat. No. 7,279,761 discloses also a proposal where comb electrodes are transferred from a non-meshing (separate combs) into a meshing interlocked state and secured therein either by a ratchet or by bistable springs. The introduction of the finger structures, etched at a spacing, into the oppositely positioned spaced gaps is critical; the sensing axis is parallel to the direction of the positioning axis.

EP 1 998 345 shows oppositely positioned comb structures that are deep-etched, staggered, non-meshing, lateral, deep-etched or formed on grooves walls. In this connection, one comb is laterally movable such that the projections or recesses which are staggered relative to each other can be transferred into a position with reduced offset or even into a symmetry position so that the capacitance is increased. The movement direction is the sensing direction. A locking function is however not provided here.

WO 02/19509 discloses meshing comb structures where the finger spacings of a stationary comb relative to a movable comb are position-dependent because the structures of the fingers and spaces that engage each other are designed as prisms with trapezoidal base surfaces.

GB 2 387 480 discloses a device that moves electrodes of a contact switch closer to each other until they reliably contact as a result of bending due to different thermal expansions in a supply line and a parallel return line of different thickness as current passes through. In doing so, by a mechanical locking action by means of a hook with a barb the contact position is moreover secured even when the flow of current is terminated. Release of the barb system is realized by a second bending device which is provided on the barb and has a similar configuration (with current supply and return line of different thermal dissipation loss and thus with different expansion). A capacitive approach is not disclosed.

In order to utilize this prior art, on the one hand, and to eliminate the existing disadvantages as they are apparent from the prior art, a method has been searched for that utilizes the existing technologies, for example, around CMOS or BiCMOS semiconductor manufacturing technologies, in a more economical way. In this context, if possible, no additional processing steps should be required but still the sensitivity of the converters of the aforementioned kind should be significantly improved. It is a further object to reduce the required material surface area (chip size) of the converter but still achieve good measuring results. A very high sensitivity of a sensor part should enable the elimination of amplifier stages or the use of simpler amplifiers for signal conditioning that, in turn, lower material consumption and thus the manufacturing cost. In summarizing the above, the invention should enable the production of sensors, for example, for accelerations, rotary speeds, and vibration measuring devices or actuators, at more beneficial production costs but with high sensitivity or effective power, for example, in actuating members, vibration transducers, relays or switches and the like. It should furthermore be suitable to optimize already existing MEMS converters by redesign and re-layout. Moreover, capacitors with higher energy storage capacity (capacitance) per used silicon surface area should be enabled by the invention. Important is also a high reliability of the function of such actuator or sensor and great yield, or less scrap, in production.

With the method according to the invention, very small separating groove widths or structure spacings relative to the structure depth can be obtained without requiring additional chemical processing steps other than those provided in the already existing standardized deep etching methods. The electromechanical sensitivity of sensors produced in this way and the force action of actuators are increased.

Existing standard processes can be employed. A further layer application onto the etched structures with its processing times, the processing risk and additional defects is not required. In general, the micromechanical structures can be formed by method steps which are well-known from semiconductor technology and which are therefore not explained in detail in this context. The method enables processing in standard wafer manufacturing facilities which support in particular CMOS or BiCMOS processes and where mask lithography, passivation, etching steps, metallization and doping are already used.

The obtainable capacitance per surface area in relation to the employed silicon surface is very high in case of vertical capacitors formed in this way.

For achieving a high aspect ratio, according to the invention the width of defined separating groove sections, basically produced according to a manufacturing process according to the prior art, is reduced by a further method step. This is realized by newly positioning at least parts of the structure parts that are completely or almost completely separated from each other. In case of incompletely separated structure parts there remain holders, preferably in the form of flexible holders, between the separating grooves after separation.

The method according to the invention enables the production of many electromechanical systems where a high aspect ratio of spaced-apart structure grooves is advantageous. For improving this aspect ratio it is therefore proposed that at least one structure element of a silicon wafer or a semiconductor component is separated almost completely by chemical and/or physical material removal relative to a surrounding part or a further structure component. Ideally, a reactive ion etching method such as DRIE, deep reactive ionic etching, is used. However, the parts that are separated in this way remain connected to each other by bending-elastic connections usually for holding and for supply lines. As a result of the removal process properties, as in etching, the separating groove width for predetermined groove depth can not fall short of a defined value. According to the invention, in a further step the position or the orientation of the separated inner structure part is changed relative to the outer surrounding part or a further structure part so that the spacing between at least two oppositely positioned formed wall sections of the separating grooves formed by removal is reduced. At the same time, of course, the spacing at another wall section is enlarged in this way. The sensing direction of the sensor or the movement direction of the actuator according to the invention is substantially independent of the direction of the positioning travel. The special feature is that the special shape caused by alternating projections and recesses in the etched groove wall enables a lateral movement of the structure parts relative to each other with the inherent spacing reduction. Those wall projections which upon etching have been formed opposite the recesses are moved into positions in which wall projection and wall projection are positioned opposite each other (but also recesses opposite recesses). The transverse or shearing movement of the spaced-apart electrode surfaces in the lateral direction normal to the electrode surfaces causes new spacing conditions. Subsequently, a fixation, preferably by a locking device, is realized.

By selecting the size of the wall projections relative to the wall recesses, the movement damping can be advantageously adjusted which is caused by the gas present in the etching grooves.

The separating groove wall sections that have been moved closer are formed as capacitive electrodes in order to store electrical charge carriers electrostatically.

For this relative change of the separated components relative to each other, different methods can be used. Either by devices from the exterior or by integrated inner devices, a force action or a torque is exerted or transmitted onto at least one of the parts that are separated from each.

After positional or orientational change of the components for changing the groove spacings, the separated structure part is permanently or irreversibly secured by suitable means. In this way, a high aspect ratio is locally achieved and maintained. The fixation can be done such that the desired converter functions are maintained in that a relative electrode movement, preferably in a direction or orientation that is different than that in which the fixation is acting, is not limited.

For material removal, ideally an etching process is used which is already present for other applications in connection with the circuit. For example, a dry etching process, in particular reactive ion etching, is advantageous. Momentarily, the best process for this purpose is reactive ion depth etching (deep reactive ionic etching, DRIE). However, other future advantageous chemical methods are not excluded in this context.

The manufacture of the structure parts can be integrated well into CMOS process or a BiCMOS processes.

According to the invention, there is an abundance of possibilities that enable the relative positional change or orientational change by means of force action or torque generation. This includes external field parameters. The gravitation, preferably earth gravitation, that causes a gravitational force, could cause for example the internal positional change of parts relative to each other by tilting a processed wafer from the horizontal position into a vertical position.

An external electrical field can, for example, induce, by means of an electrically highly charged body laterally to the converter, forces or torques on the movably supported and differently charged structures that cause a movement thereof relative to the charged body.

By applying an electrical potential to the electrodes, located at the separating groove walls, the resulting electrical field can effect the required attractive force in order to achieve the target position. The charge supply can be realized advantageously by separate lines.

The same holds true for an external magnetic field. Here, the interaction with an inner magnetic field, for example, as a result of current flow, must be realized by at least one of the parts separated from each other. The magnetic field is generated externally by means of a permanent magnet or an electromagnet. In order to be complete, it should be mentioned that the permanent magnet structures can be applied also onto the movable parts in the converter device.

Temperature-caused deformations of bending-elastic connections that are suitably designed for this purpose as a result of different thermal expansions, cold contraction can also be utilized for force actions on the structure parts that are to be moved relative to each other.

It is also possible, even though more complex, to directly couple an actuator, for example, a pushbutton, with an elastic cap of high friction for protecting the surface of MEMS device. This actuator can then pull the structure part directly in the direction of the nominal position after placement onto the separated structure part and simultaneous fixation of the surrounding part. Rotation is possible also, even additionally. Also, the surrounding part with simultaneous fixation of the separated structure part by means of an external actuator can be positionally or orientationally changed. Or, the relative position as well as the orientation of two neighboring structures relative to each other can be changed in this way.

The law of conservation of energy enables the advantageous use of inertia of the structure part for the change of position or orientation. When the microelectromechanical device is accelerated briefly in the direction opposite to the direction of positioning or orientation or is slowed down from a uniform movement, for example, by means of a shaking device, or is accelerated or slowed angularly, for example, by means of a turn table, the acceleration forces act on the loose structure parts or structure parts that are joined by elastic connections, which in this way are caused to move relative to the surrounding parts.

Also, centrifugal forces (centrifugal forces) can be used advantageously. For this purpose, the microelectromechanical device (for example, the wafer or a MEMS converter) are caused to rotate about an axis. For this purpose, the separated structures are advantageously positioned relative to the rotation axis such that the forces in radial direction act in accordance with the invention on the separated bodies such that the displacement into the operative rest position of the structures or also rotation into an appropriate orientation is effected.

A further method of transmitting movement energy onto the moveably supported structure part is the utilization of the capability of the structure to vibrate and its resonance frequency. By means of vibrating systems, preferably by means of vibrators, the latter is excited to generate vibrations that are in the range of a resonance frequency of the structure part.

Also suitable is the energy transmission through an elastic impact from the exterior.

For the above mentioned methods, in principle additional structures within the microelectromechanical devices are not necessarily required. Still, their own drive devices within them can be provided, also as assisting means, for relative positioning or orientational change.

These inner drive devices are preferably electrostatic comb mechanisms.

However, it is also possible to have magnetic drives. For producing the magnetic fields, conductors with current flowing through can be utilized.

Heating devices in the form of electrical loss resistors can cause as a result of current flow the deformation of defined connecting structures to the separated structure part as a result of different thermal expansion. Applied to different locations or in different position, this effects a relative displacement or rotation of the connected parts relative to each other.

A similar action is possible when thermally caused deformations of suitable separated structures upon current flow push away the structure part.

It can be advantageous to combine different devices for generating a force action or torque.

The force action or the torque should be designed to be sufficient such that the effect of counteracting spring forces, in particular of spring forces of elastic connections, can be surpassed. Accordingly, the force action is expediently such that mechanical energy stores, such as elastic springs, are charged or tensioned.

The fixation or securing action of the separated part after positioning or new orientation is advantageously mechanically realized by means of structuring of locking catches on the microelectromechanical device, preferably assisted by restoring springs, that force sliding lugs into locking positions, for example. Spring-supported toothings, in particular with different steep flanks in the direction of the movement, can be used also as a locking connection. These are structures comparable to those known from cable ties.

When a bending beam is formed on at least one wall of the separating groove walls and is pressed strongly against a projection of the opposite wall and, as a result of this, is bent, the contact angle between the bending beam and the projection may become flat. This has the result that a reduced friction as an obstacle becomes surmountable for the tensioned bending beam and the latter therefore can jump into a further position behind the projection as a result of the spring force.

The thus embodied “ratchet-like” arrangement of bending beam and projection can be realized such that a unidirectional movement is generated. In this connection, a change, preferably a reduction of a considered separating groove section, can be realized but not an enlargement.

However, several locking positions can be provided also. This enables during the displacement a control of the selection of any position of different nominal positions in one or several steps so that different converter properties can be adjusted, possibly also reversibly. In this connection, the already mentioned force actions and devices are employed again. Additional factors are to be taken into account in this context for the selection of a defined position, for example, the duration of a force action, the number of defined force actions but also the amplitude of the action within a defined amount of time.

Alternatively, electromechanically acting microactuators can be provided on the device for the fixation of the positioned or newly oriented structure and for maintaining the local high aspect ratio.

Thermal deformation of structures is also suitable for locking whereby the latter at least partially engage the travel path. The freedom of return movement of the moved part relative to the other parts is prevented by blocking structures, preferably, by lock bolts.

However, the entire freedom of movement, preferably in those directions or applications that require no sensitivity subsequently, can be limited. A targeted gluing, wedging, soldering or destroying of structures that have been formed for maintaining a defined relative movement are further methods for fixation after completed aspect ratio optimization. For example, also thermal melting of a resistor through which current is flowing can permanently or reversibly prevent the mobility of a separated and positioned part, at least in the direction or the rotational direction from which the approach of the separated parts has been realized.

In addition to the method according to the invention for producing microelectromechanical converters, defined microelectromechanical converters are also the subject matter of this invention.

A characteristic feature of such a converter according to the invention is the presence of parts that are separated at least partially from each other but after separation are moved closer such that the aspect ratio at the defined positions in between is stably enlarged. Preferably, at least one part is structured from another. Therefore, one part is the structure part and one is its correlated surrounding part. However, also two elastically connected structure parts can be structured at a spacing relative to a surrounding part and also connected to it by means of elastic connections (springs).

Between the parts there are separating grooves that are partially bridged. Ideally these grooves have sections with a course extending back and forth, in a winding shape, or zigzag shape or meandering shape. The groove sidewalls are embodied in these sections as electrodes with oppositely positioned counter electrodes, preferably by known doping methods.

Physical considerations and the analysis of presently existing etching processes show that by means of the approach method presented herein an aspect ratio in the operative rest position can be configured that represents a multiple of the current aspect ratios in the operative rest position in known MEMS electrodes.

Therefore, one feature of the converter type according to the invention presented herein is an aspect ratio which is within a value range of 15 to 500, preferably the range is between 20 to 200. In particular, the aspect ratio has a value in a separating groove section determining the sensor properties which is at least 25 but preferably is as constant as possible across the section.

The depth of the separating groove as well as the spacing caused by the displacement of parts can be defined very precisely by structures that are defined by mask lithography but the surface structuring of the groove walls can have a defined process-related residual roughness which has an effect on the breakdown resistance and the average electric permittivity particularly in the near range.

The areas with the very high aspect ratios according to the invention are, for example, designed as electrodes and, in order to design a large surface area in a small space, are preferably embodied comb-like with meshing projections that do not contact each other. On the converter, as a result of the manufacturing process, structures are provided or devices that have the task of securing the structure that has been separated by the manufacturing process in an operative rest position or orientation. Securing serves the purpose of keeping constant the average value of the aspect ratio also in sensor or actuator applications but to not limit the sensor or actuator properties.

In known MEMS methods with mechanical approach, currently the sensor or actuator directional axis is used also as a direction of approach so that the manufacturing tolerances and the mechanical clearance of the locking actions also may have a direct effect on the converter size. In the solution presented herein, the capacitive converter sensitivity within the etched separating groove sections that have been moved closer is substantially oriented in the direction of the normal of the tangential surfaces of the etched groove walls.

The operative rest position or orientation differs therefore geometrically from the relative production position of the parts structured from a single piece before separation and during separating groove formation.

The converter according to the invention has therefore separating groove sections with an average width that has a fraction of the average width of all of the separating grooves produced on this converter. By means of this type of capacitive electrode arrangement in this section, an advantageously high sensitivity of a sensor configured in this way or a high performance of an actuator designed in this way is provided.

According to the invention, it can be advantageous that at least one inner drive device is integrated in order to increase the aspect ratio. This drive device can be an electrostatic comb drive. Alternatively, it can be a drive that utilizes magnetic fields of conductors through which current is flowing.

Also, a thermally activated drive can be provided. The latter can be embodied as a component of different shape and/or material properties wherein the different thermal expansion that is caused by current flow causes the movement. Shape changes of defined connections to the separated structure part can be forcibly achieved in this way so that a relative object displacement or rotation of the structure part relative to the surrounding part is possible by applying current.

Specially embodied pushing elements between the separating groove sections can be widened in order cause advantageously a reduction at another side by temperature-initiated length increase, by electrostrictive or magnetostrictive elements.

For increasing the effect, they can also act similar to bimetallic strips. In the form of spirals or arcs, an appropriate torque is effected thermally which by means of a lever can exert directly pressure or rotation onto the element to be displaced or rotated when appropriate current flow for heating or heat supply from the exterior is realized.

As an alternative or as a supplement, devices for enhancing the effect of external devices for force action or torque transmission can be provided also in addition to the internal drive devices. Thermal elements can be considered which upon high environmental temperature become effective or magnetic materials that are attracted or repulsed by an external magnetic field, such as iron, nickel, or cobalt or alloys or rare earth metals and the like. Also, a defined support of the movable structure part by means of springs can effect a very defined resonance property that is, for example, excitable by ultrasound and in this way effects the desired change result.

Assist devices are also special supports as a result of structuring which enable sliding in one direction, rotation about an axis or twisting of a suspension capable of undergoing torsion.

When bending-elastic connections between the structure part and the surrounding part or between two separated structure parts are present in a locked deflected position, a restoring force that is effected as a result of the bending stiffness enables again, in case of a possible release of the locking action, a return of the moveable part into the production state with minimal aspect ratio. Moreover, by the counterpressure of the spring force the locking action is secured.

The separated structure part has expediently limited movability. For this purpose, either the shape of the structure or the groove course or the arrangement and design of the bending-elastic connections is used. It is expedient that the component after manufacture has only two degrees of freedom for movements relative to each other. Accordingly, in the path of at least one direction, locking devices are provided in accordance with the invention. They serve the purpose of blocking relative movement of the structure part relative to the surrounding part permanently or irreversibly.

Advantageously, bending-elastic connections can be arranged between the structure part and the surrounding part which enable a rotation about a limited angle. In order to prevent a return rotation that is elastically effected or caused by bending stiffness, fixation elements, preferably in the form of locking pawls engaging toothed flanks, can be provided. By means of asymmetric tooth flanks, it is possible to control a locking action in only one direction.

For locking, the converter according to the invention can also have wedges, adhesive spots or soldering spots that prevent transition from the operative rest position back into the production position.

Locking devices in the form of locking catches can be advantageously constructed of springs with hooks and barbs. Accordingly, at least one of the springs with hook can be formed, respectively, on one of the respective parts of the structure separated from each other. The locking catch that is constructed in this way should however not impair, if possible, or impair only minimally, the required sensing or actuating movement or rotation.

Microbars, electromechanical microactuators may serve as mechanical actuating members. However, also thermally changeable structures can be used for blocking the path by means of thereby driven sliding bolts transverse to the movement paths of the separated and positioned or reorientated structure part.

It is advantageous when at least one bending beam is arranged at least at one wall of the separating groove walls and the opposite wall has at least one projection, preferably with tooth flanks. In this connection, the spring stiffness of the bending beam and the sliding friction between the bending beam surface and the surface of the projection can serve to to require an increased work for overcoming them.

This combination of bending beam and projection is expediently arranged as a locking pawl. It has a “ratchet-like inhibiting action”. A mechanical limitation of the bending travel of the bending beam and its orientation relative to the shape of the projection enables blocking of the movement in the opposite direction. In this context, the tooth flanks are preferably asymmetrically designed.

The presence of several locking positions can be advantageous in order to adjust different converter properties during or after production.

As possible microelectromechanical converters designed in accordance with the invention can be high-sensitivity or very small sensors for travel, vibration, acceleration, speed, rotary speed, force, pressure or torque, respectively, for such physical parameters that can be converted into them.

As an application for actuators, micromotors for linear or rotating movement as well as vibration generators (vibrators) are provided. Also, micropumps, microdrives, preferably for light modulators on mirror(arrays)) but also mechanical microswitches or relays can have the features according to the invention.

An adjustable capacitor can also be designed in accordance with or comprising the described properties.

Such microelectromechanical converters are advantageous as a component of an integrated microelectronic circuit which comprises further circuit parts such as those for amplification and signal processing or signal conversion.

The present invention will be explained in more detail with the aid of the following drawings.

It is shown:

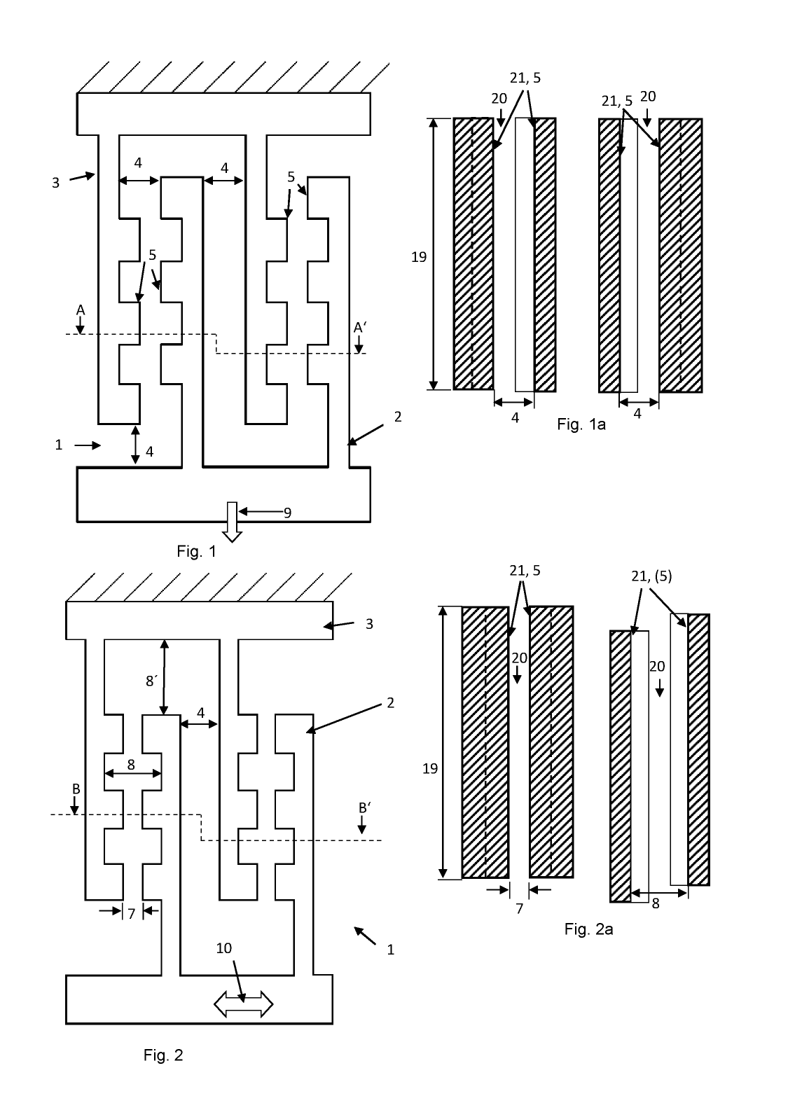

FIG. 1 shows a sketch of a first possible embodiment of a characteristic part of a microelectromechanical converter 1 with two structure elements 2, 3 movable relative to each other in a production position before positioning in the operative rest position.

FIG. 1a shows the section A-A′ with production-technologically caused spacings 4 that also depend on the structure depth 19.

FIG. 2 shows a sketch of the first possible embodiment of FIG. 1 after positioning from the protection position into the operative rest position.

FIG. 2a shows the section B-B′ with reduced spacings 7 but also enlarged spacings 8.

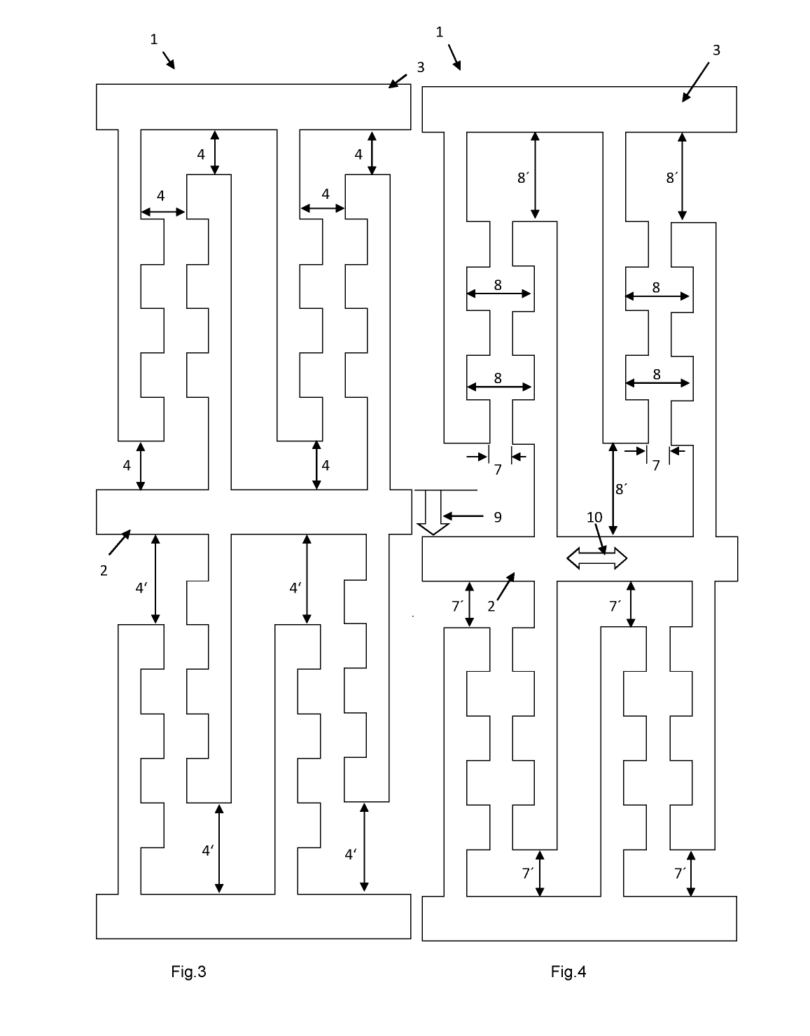

FIG. 3 shows a sketch of a second possible embodiment of a microelectromechanical device 1 or a part of a microelectromechanical converter with two (up to three) structure elements 2, 3 movable relative to each other in production position before positioning in the operative rest position.

FIG. 4 shows a sketch of the embodiment of FIG. 3 after positioning in the operative rest position.

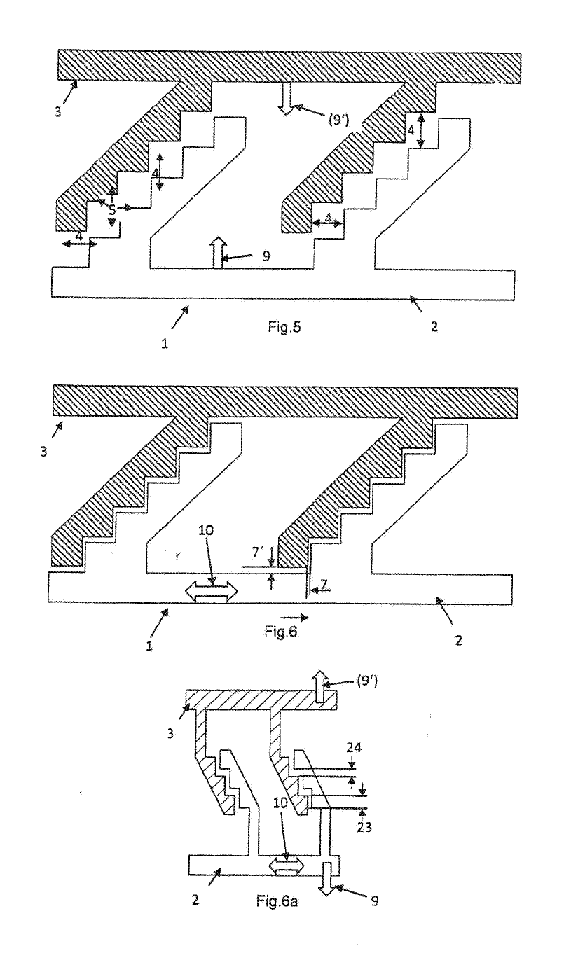

FIG. 5 shows a sketch of an alternative electrode structure design in production position before approach of the electrodes 5.

FIG. 6 shows the structure of FIG. 5 after positioning in the operative rest position and with electrodes 5 moved closer. FIG. 6a shows an alternative with reverse positional change in the operative rest position after positioning.

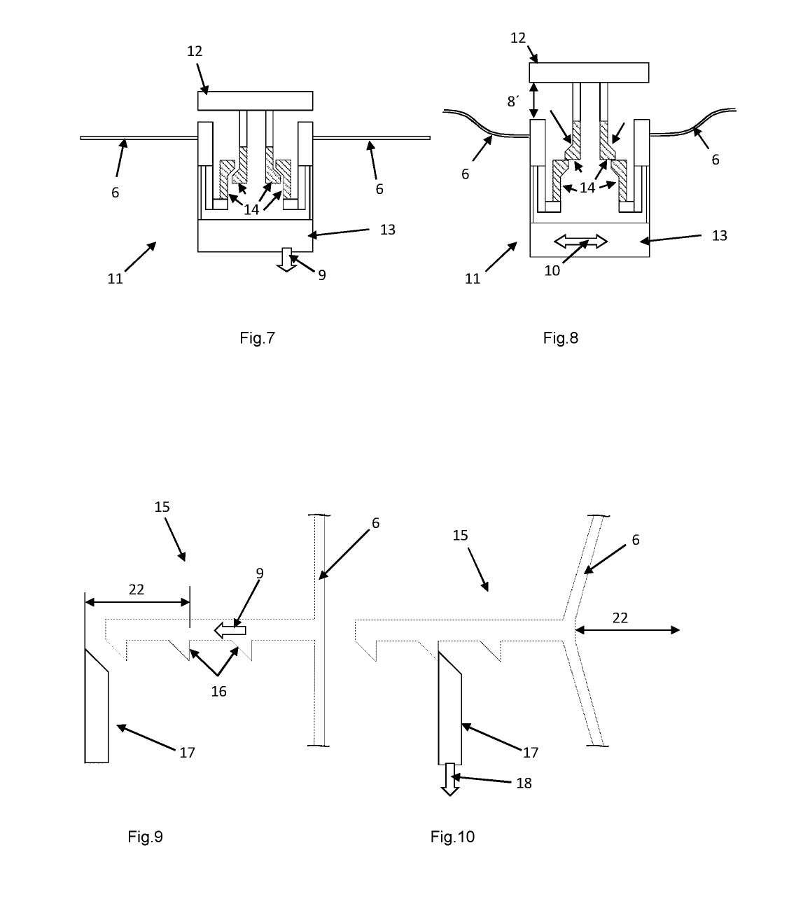

FIG. 7 shows a possible single-stage irreversible locking device before positioning in the operative rest position.

FIG. 8 shows a the locking device of FIG. 7 after positioning.

FIG. 9 shows a possible multi-stage, at least temporally irreversible, locking device in production position before positioning.

FIG. 10 shows the multi-stage locking device of FIG. 9 in second locking position and with tensioned counter spring 6.

### DESCRIPTION OF EMBODIMENTS

The comb-like structuring shown in FIG. 1 of a device 1 according to the invention has, after a typically employed dry deep reactive ion etching process, defined spacings 4 and a defined depth 19 based on which a defined aspect ratio (structure depth to structure spacing) is predetermined. Ideally, by means of the etching masks a groove width is produced that represents a good compromise between etching duration and etching-related surface area loss.

The device 1 is comprised herein of two components 2, 3 that have meshing tongues. The surfaces of the tongues have projections. These projections are determined by design and mask lithography. The technology-related minimal etching width for the desired etching depth 19 can also be adjusted herein as a greater groove width 4. As an example, three projections per tongue are illustrated herein. The projections of neighboring tongues are arranged opposite each other and staggered to each other wherein one tongue belongs to component 2 and the other belongs to component 3. Component 2 is herein the separated structure part.

Component 3 can also be a separated structure part but also a surrounding part that is, for example, fixedly connected to a housing. Because of the separation, the parts 2, 3 can be moved relative to each other. When the structure part 2 in FIG. 1 is moved downward in direction 9, the projections on the oppositely positioned tongues reach an antiparallel or mirrored position. The result is illustrated in FIG. 2. The minimal spacings 4 change, on the one hand, to greater spacings 8 and, on the other hand, to smaller spacings 7. This can be seen even more clearly in the section drawings FIG. 1a and FIG. 2a. Since the surfaces of these tongues, in particular the projections, are designed such that they can carry charge carriers, capacitance surfaces are produced in this way. Supply line for applying or discharging charge carriers or measuring lines for detecting the potential differences are provided (not shown here). According to FIGS. 1, 1a, the potential surfaces 5 are substantially spaced with respect to the projections and recesses at the same spacing from each other in the initial position (after the etching process). Accordingly, in approximation a capacitance is produced that is proportional to the surface area of the oppositely positioned electrode surfaces A 5 and indirectly proportional to the distance d 4.

C=prop. A/d (1.1)

Equation 1.1 mirrors the relation before movement. Strictly speaking, in the present example two times six partial surfaces A₁ are present wherein the sum of these surfaces determines the total capacitance Cᵥ.

Cᵥ=prop. 12A₁/d (1.2)

By the movement in the direction 9 according to FIG. 2 by a travel, a partial capacitance changes advantageously to C₁>Cᵥ as a result of the approach by d₁ which corresponds to the height of the projection.

C₁=prop. A₁/(d−d₁) (2.1)

Another partial capacitance changes however in a disadvantageous way to C₂<Cᵥ.

C₂=prop. A₁/(d+d₁) (2.2)

The sum in the instant example after the positional change of the structure part is:

Cₙ=prop. (6A₁/(d−d₁)+4A₁/(d+d₁) (2.3)

In FIG. 1 and FIG. 2 d₁=d/2. This results in a greater capacitance of:

C_{n0.5}=prop. (12A₁/d+8/3A₁/d)=prop. 14.66A₁/d (2.4)

Accordingly, a 22% increase (C_{n0.5}/Cᵥ=14.66/12) of the capacitance is obtained for cutting in half the distance of individual electrode spacings, as shown here. For the same sizes, in case of five projections on two tongues each, more than 26% and for 10 projections on two tongues already 30%, for 100 projections on two tongues theoretically 33% are obtained.

Higher projections with 90% of the size in comparison to the spacing 4 would result in, for example, five times as high a total capacitance.

C_{n0.1}=prop. (6A₁/(0.1d)+4A₁/(1.1d) (2.5)

C_{n0.1}=prop. (60A₁/d)+40/11A₁/d)=prop. 63.63A₁/d (2.6)

Accordingly, more than 500% increase (C_{n0.1}/Cᵥ=63.63/12) of capacitance is obtained when the spacings of individual electrode spacings is reduced to one tenth. This is not illustrated in FIG. 1 or FIG. 2.

In the target position according to FIG. 2 of the structure part 2 and the further part, also surrounding part 3, the direction 9 or the opposite direction is blocked or greatly limited for movements but a movability in directions 10 that are perpendicular thereto remains substantially intact in particular for sensors or actuators

In addition to the above mentioned capacitance increase resulting from the method according to the invention, a sensitivity increase is achieved also for the product in the end. Since the change delta C across the distance change delta d in the derivative of the equation is entered as a square function, the sensitivity also increases by a square function In the example of FIG. 2, the sensitivity relative to FIG. 1 is greater by almost 50%. In a structure with spacing reduction to 1/10, the theoretical sensitivity increase would be greater than 25 times (!) in comparison to the prior art. Accordingly, an amplifier with a factor 25 can be saved or the amplification factor can be reduced. Significantly smaller sensors can thus provide the same sensor performance. The power consumption of actuators can also be reduced.

FIG. 3 shows the microstructure of FIG. 1 in a second embodiment. The embodiment according to FIG. 3 differs from the embodiment according to FIG. 1 in that the surrounding part 3 is present on two sides of the separated part. In this way, the required length of the tongues per surface area of the semiconductor base material (for example, silicon) is reduced so that more favorable mechanical properties will result.

The movement of the centrally positioned structure part 2 after the etching production is again carried out in the direction 9 relative to the surrounding parts 3 into the position according to FIG. 4. Again, projections at the meshing tongues are moved from an asymmetric position into a symmetric position and locked subsequently. The locking elements are not illustrated in FIGS. 1-6 for simplifying the drawing. In FIGS. 7-10 simple embodiments are schematically shown.

In this embodiment in FIG. 3 or FIG. 4, a unidirectional direction 9 for the approach of the electrode surfaces is also provided and a preferably bidirectional direction 10 for the converter function.

Alternative structures of FIGS. 1-4 are illustrated in FIG. 5 and FIG. 6. Structuring in FIG. 5 is embodied stair-like. By movement in the direction 9, but also by simultaneous movement of both parts 2, 3 relative to each other in the directions 9, 9′, the electrode surfaces positioned opposite each other approach each other. The result in FIG. 6 shows the moved-in parts 2, 3 and the operative rest position. The process-related spacing 4 of the stair-like profiled tongues facing each other is brought closer in the direction 9 to a spacing 7. After locking the movability in the direction 9, the movability in the direction 10 for the function of the converter is maintained sufficiently. For better differentiation from the part 2, the part 3 is illustrated cross-hatched. The five steps of the two slanted tongues are moved in FIG. 6 to the rest position with a capacitance of

C=prop. A/d (6.1)

The initial capacitance after the etching process is significantly determined by the stair edges that position the charge carriers with different polarity closest to each other. In a first approximation, one can use as an effective capacitor surface area A_{w} approximately the tongue length times the tongue width being equal to the depth t of the component; the effective capacitor spacing d_{w} is a value that is between the spacing of the edges and the etching width; in a first estimation, half the diagonal between the electrode surfaces that delimit the separating groove can be assumed:

Cᵥ₁=prop. (10*d/sqrt2*t)/(d/sqrt2)=prop. 10*A₁/d (5.1)

Accordingly, in a first approximation, the capacitance of a tongue pair before approach can be proportional to the sum of all step surfaces and indirectly proportional to the spacing. This value corresponds thus in first approximation to the value as it is achieved in the prior art. The capacitance after a change, for example, to a spacing that is 1/10 of the production spacing is as follows:

Cₙ₁_{_{—}}_{0.1}=prop. (10A₁/(0.1d)=prop. 100*A₁/d=Cᵥ*10 (6.2)

The capacitance is here 10 times as large, i.e., twice as high an increase in value as in the examples of FIG. 1 to FIG. 4.

The sensitivity change is however more complex because here the step surfaces experience a spacing change parallel to the long side of the sketch sheet and a surface area change parallel to the short side of the sketch sheet.

With the aid of a further example in FIG. 6a, the advantage for damping will be explained. After positioning in the proximal position of the parts by the method according to the invention in the direction 9 or 9 and 9′, a further movement for this direction is locked by suitable means, the movability in the direction of the sensing axis 10 (here orthogonal to the positioning direction) remains however intact within the remaining clearance. One can see here that even an outward movement can lead to an inner approach of the sensor surfaces. The electrode surfaces delimit substantially communicating spaces that are filled, for example, with gas, usually air, in accordance with the ambient air pressure. A type of space V₁ is delimited by the vertically illustrated overlapping surfaces of the overlapping length l, 23, the second type of space V₂ is delimited by the overlapping surface of the length g, 24. The groove spacings along these overlapping lengths l, g are smaller at 23 because of the steps than at 24.

The groove depth is constant. Accordingly, the compressible/displaceable volume V₁ is

V₁=˜t*l*s₁ (6a.1)

when t is the depth, l is the overlapping area 23, and s₁ the spacing of the overlapping surfaces.

V₂=˜t*l*s₂ (6a.2)

The same applies in regard to V₂ with lateral surface t*g and the spacing s₂. With the size determination of L and g, a direct effect on the space ratios can be provided V₁:V₂ provided.

l+g=L (6a.3)

accordingly,

V₂−˜t*(L−l)*s₂ (6a.4)

The step width corresponds to the depth t of the component, L is the length of the steps and the height H of the steps results from the difference in spacings.

H=s₂−s₁ (6a.5)

and thus

V₂=˜t*(L−l)*(H+s₁) (6a.6)

In the operating position, V₁ as well as V₂ are varied spatially. When a change of e.g. s₁/2 is performed, the volume V₁ is cut in half. The air quantity therefore must be compressed and displaced accordingly. V₂ has however a constant proportion and a variable proportion.

V₂=˜t*(L−l)*H+t*(L−l)*s₁ (6a.7)

For simplifying the explanation, it is assumed that L−l has the same spacing as s₁ and H as well as L are three times as large as s₁. Then the volume Vᵥ₂ before compression is

V₂ᵥ=˜t*(s₁)*3s₁+t*(s₁)*s₁=˜4t*(s₁)² (6a.8)

and accordingly

V₂ₙ=˜3.5t*(s₁)² (6a.9)

Here, the relative change of the second volume is 12.5%. For V₁ it follows:

V₁ᵥ=˜2t*s₁² (6a.10)

V₁ₙ=˜t*s₁² (6a.11)

The pressure change for the gas volume in V₂ₙ is thus less than for the volume V₁ₙ and therefore by pressure compensation also the total pressure change is advantageously reduced. Accordingly, in comparison to the prior art, a reduced damping action is provided.

Non-linearities in the capacitance changes can be well linearized by differential arrangements, for example, as shown in FIG. 4, wherein the lower part then must be mirrored.

In the basic configuration, for example, etching can be done to a depth of 250 μm (with aspect ratio 1:20) and then the parts can be displaced relative to each other until 500 nm spacing between the electrodes is reached. This would lead to an aspect ratio of 500 (!).

For fixation of the parts, the circuit must have locking devices as described. Two examples of such devices are illustrated in FIGS. 7-10.

FIG. 7 shows a locking catch 11 in an embodiment formed during the process with locking elements 14 in the form of hooks with springs, the hooks are slanted in the movement direction. Accordingly, they glide by pushing away the lateral springs past the counter hooks and are then returned by spring force past the hook. Additional bending springs 6 tension the locking device and press the hooks against each other wherein the contacting side here has no slanted edge. The movement of the parts 12 and 13 is unidirectionally moving apart only up to an end position as in FIG. 8. The parts 12 and 13 in the device of the present invention are each rigidly connected with the structure parts 2, 3 or formed in these parts.

A movability along the direction 10 is maintained by this device within certain limits.

The use of several locking stages provides a possibility to adjust stepwise a nominal capacitance and to secure it. FIGS. 9 and 10 illustrate a possible locking pawl which represents a locking device 15 with several rest positions and uses teeth with different flanks 16. The toothed rack moves against the bending beam, bolt 17 with slanted end, the respective position is secured by the rear sides of the teeth designed orthogonally to the movement direction and of the beam or bolt. Release of the locking action can be realized only by transverse movements or forces transverse to the movement direction of the toothed rack, for example, by movement of the beam or bolt in the direction 18.

The above description of the embodiments according to the present invention serves only for illustrative purposes and not for the purpose of limiting the invention. In the context of the invention various changes and modifications are possible without leaving the scope of the invention as well as its equivalents.

### LIST OF REFERENCE NUMERALS

1 microelectromechanical device, MEMS converter (part)
2 (separated) structure part
3 (remaining) surrounding part (detail) or second structure parts
4 minimal separating groove width (4′) caused by the production technology by the structure depth or accordingly selected greater separating groove width (4′)
5 capacitive electrode (surface)
6 bending-elastic connection
7 reduced spacing as a result of changed relative (here e.g. lateral) structural position
7′ reduced spacing as a result of movement of two boundaries surfaces toward each other
8 enlarged spacing as a result of changed relative (here e.g. lateral) structural position
8′ enlarged spacing as a result of movement of two boundary surfaces away from each other
9 direction of permanent or irreversible change of position (lateral, axial or tangential (in particular for rotary movements); also opposite movement (9′)
10 optional sensing direction or optional forced actuator movement direction (linear with lateral movement clearance, circular for rotary angle clearance, or blocked without movement clearance)
11 fixation device (locking catch)
12 part of 11 that exists in or is formed in stable connection with 2 (3)
13 part of 11 that exists in or is formed in stable connection with 3 (2)
14 locking elements with springs and hooks
15 fixation device with several locking positions
16 projections, in particular teeth, with different flank steepness
17 locking tongue (also lock bolt or locking beam)
18 direction for an (optional release)
19 structure depth
20 separating groove within a section
21 separating groove walls
22 spacing-reducing travel for defined looking position
23 overlap width of the compression capacitance in the operating position
24 overlapping width of the shearing capacitance in the operating position
A-A′ section 1
B-B′ section 2

The invention is defined in particular by the claims. Specific embodiments as well as further embodiments thereof will be discussed in the following.

Inter alia, the invention concerns a method for manufacturing microelectromechanical devices (1) with high aspect ratio, characterized in that the method comprises the following steps:
at least one structure part (2) of a silicon wafer or a semiconductor component with a thickness that is minimal in relation to the surface expansion is separated by chemical and/or physical material removal with technology-related aspect ratio relative to a surrounding part (3) or a further structure part, wherein bending-elastic connections (8) between the structure part (2) and its surrounding material may remain;
a method step follows for reducing the spacing (4 toward 7) between at least two oppositely positioned wall sections of the separating grooves (20) produced by removal and preferably embodied as capacitive electrodes (5) by mechanical relative, primarily lateral, position or orientation change of the separated structure part (2) relative to the surrounding part (3) or a further structure part of the semi-conductor surface by means of inner and/or outer devices that exert or transmit a force action or a torque on at least one of the parts (2, 3) separated from each other,
after reduction of the spacing (4) in a defined separating groove section (20), at least one separated structure part (2) is permanently or irreversibly secured by a device (12, 15) against an increase of the spacing (7) of the wall sections that have approached each other.

In such a method, for producing the structure parts (2, 3) a CMOS process or a BiCMOS process can be used.

The force action or the torque can be caused by direct coupling of at least one actuator, preferably at least one pushbutton with elastic cap of high friction wherein the pushbutton or pushbuttons, upon placement onto at least one separated structure part (2) and simultaneous fixation of the surrounding part (3), pulls or rotates the structure part (2), or several such parts, or, in reverse the surrounding part (3) with simultaneous fixation of at least one separated structure part (2), the surrounding part (3), directly in the direction (9) of the nominal position or nominal orientation, as needed.

Alternatively, the force action or the torque can be realized by utilization of the inertia of at least one structure part (2) wherein preferably the microelectromechanical device (1) is briefly accelerated or angularly accelerated in opposite direction relative to the direction (9) for positioning or relative to the rotational direction (9) for the orientation.

Alternatively, the force action can be caused by utilization of the centrifugal force wherein preferably the microelectromechanical device (1) is caused to rotate and the arrangement of the separated structure parts (2) is realized such that the radially acting forces promote the required movements or rotations of these parts (2) into the nominal position or nominal orientation.

However, it can also be generated by any elastic impact from the exterior.

In another alternative, the force action or the torque is triggered by application of electric potential to the electrodes (5) provided on the separating groove walls (21) by means of the generated electrical field, preferably by separate supply lines.

In the method according to the invention, combinations of different devices of the afore described kind can be used for generating the force action or the torque. The force action or the torque can be realized in addition also against spring forces, in particular against spring forces of elastic connections (6).

In the method according to claim 9, by the force action or the torque at least one bending beam (6, 17) that is provided on at least one wall of the separating groove walls (21) can be forced so strongly against at least one projection (16) on the opposite wall and bent to such an extent that as a result of the contact angle and the additional spring force the friction that is acting between bending beam and projection is overcome and the beam (17) jumps into a further position behind the projection (16).

In this context, the arrangement of bending beam (17) and projection (16) can be realized for example in such a way that a unidirectional movability is provided that enables only one modification, for example, preferably a reduction, of a separating groove section (20) under consideration.

In the method according to the invention of one of the two last mentioned kinds, several locking positions on a fixation device (15) can be provided wherein during the positioning method selection of one position of the different nominal positions is controlled in one step or several steps in order to adjust defined converter properties.

The invention concerns in a further aspect a microelectromechanical converter (1) with at least one structure part (2) that relative to a surrounding part (3) is at least partially separated, preferably secured by elastic connections, and electrodes (5) on oppositely positioned, preferably meandering or zigzag-shaped or of a winding shape or of a course extending back and forth, preferably parallel separating groove walls (21) that section-wise are arranged between at least two such separated parts (2, 3) characterized in that this converter (1)
has an aspect ratio in the operative rest position within a section of the separating groove (20) that is in a range of 15 to 500, preferably in a range of 20 to 200, in particular has a constant value as much as possible preferably across the section, the value being at least 25 times the structure depth (19) relative to the separating groove width (7), and
is provided with a device (11, 15) which secures or fixes at least one separated structure part (2) relative to a further structure part (3) in an operative rest position or operative rest orientation wherein in this context the relative position and orientation of these separated structure parts (2, 3) that are manufactured from a single piece is unequal relative to that existing before or during production of the separating groove.

This microelectromechanical converter (in the following for short: converter) can have separating groove sections (20) that have a smaller width (7) than the average width, preferably a fraction of the average widths of all of the grooves manufactured on this converter (1), in the operative rest position.

In the converter according to the invention, at least one bending beam (17), at least on one wall of the separating groove walls (21), can be provided and at least one projection, preferably with tooth flanks (16), can be provided on the opposite wall, wherein the spring stiffness of the bending beam (17) and the sliding friction between the bending beam surface and the surface of the projection requires greater work for overcoming the transition.

In the converter (1) according to the invention, an adjusting element on a joint or a pivot or a bending beam (17) and at least one projection (16) can be arranged ratchet-like, preferably as a locking pawl, or preferably a mechanical limitation of the actuating element in one direction or of the bending travel of the bending beam as a locking elements can be provided, for which purpose the orientation of the actuating element or of the bending beam in combination with the shape of the projection, that is preferably asymmetrically toothed, can have pitch angles for blocking that in one direction are slidable and in the other direction are non-slidable.

Moreover, in the converter (1) according to the invention, several locking positions can be provided on the locking device which stabilizes at least one structure part (2) relative to another structure part or the surrounding part (3) either permanently but releasably or irreversibly in a proximal position of the electrodes (5).

The converter according to the invention of one of the aforementioned kinds can be a sensor for travel, acceleration, force, vibration, speed, rotary speed, pressure or torque or an actuator in the form of a micromotor for linear or a micromotor for rotating movement or of a vibration generator (vibrator), of a micropump, of a microdrive, preferably for light modulators on mirror (arrays)), or of a mechanical microswitch or of a relay.

The converter can be a component of n integrated microelectronic circuit.

In summarizing the above, the invention concerns inter alia the following aspects:
A. Method for producing microelectromechanical devices (1) with high aspect ratio in which at least one structure part (2) of a silicon wafer or of a semiconductor component with a thickness that is minimal relative to the surface expansion is separated by chemical material removal, preferably reactive ion depth etching (deep reactive ionic etching, DRIE) and/or physical material removal with technology-related aspect ratio relative to a surrounding part (3) or a further structure part, wherein bending-elastic connections (6) between the structure part (2) and its surrounding material may remain, that enable a relative movement of the parts (2, 3) in at least one degree of freedom, characterized in that by means of inner and/or outer devices a force action and/or a torque is exerted or transmitted onto at least one of the parts (2, 3) separated from each other in such a way for reducing the local separating groove spacing (4 toward 7) such that the thereby caused lateral and relative movement and/or rotary direction (9) of the parts (2, 3) relative to each other, in particular the resulting transverse movement or shearing movement, is realized primarily independent of the orientation of those normal vectors of at least parts of the wall sections of the separating grooves (20) produced by removal that are embodied opposite each other and staggered to each other, that are embodied as capacitive electrodes (5) in the form of wall projections, and in that upon reaching a target position with a reduced local separating groove spacing (7) at least one separated structure part (2) is secured permanently or irreversibly by a device (12, 15) against an increase of the spacing (7′) or against decrease of the spacing (8′), so that a movement in axial or rotary direction (9) is impaired.
B. Method according to aspect A in which the force action or torque generation for relative positional change or orientational change is caused as a result of one or several of the following causes:
   attraction of masses (gravitation) between the mass of the earth and the mass of at least one separated structure part (2) by orientation relative to each other;
   forces between electrical charges (electrical field), preferably caused by a highly electrically charged body which is positioned in the direction of that side of the at least one structure part (2) provided with charges in which the structure part (2) or the structure parts are to be moved translatorily relative to the surrounding part (3) to the nominal position, or by which a torque as a result of a suitably arranged elastic or torsion-capable suspension of the at least one structure part (2) is generated so that the latter thereby is rotated into the nominal orientation position, or by generating these forces by applying an electrical potential to the electrodes (5) provided on the separating groove walls (21), preferably by separate supply lines;
   magnetic forces by permanent and/or electric magnetism preferably by the interaction with a field as a result of a current flow through at least one of the parts (2, 3) separated from each other, on the one hand, and the magnetic field of an external permanent magnet or an external electromagnet;
   length change by electrostriction or magnetostriction of structure connecting parts;
   thermally caused length change or deformations as a result of different heat expansions of material structures of an appropriate configuration between the separate parts (2, 3) for relative orientation and/or positional displacement as a result of a temperature change of the environment.
C Method according to aspect A in which the force action or the torque is achieved by mechanical energy supply in one form or several forms of the group: vibration excitation, acceleration or angular acceleration against inertia, rotation for generating centrifugal forces, momentum or angular momentum transmission, wherein the microelectromechanical device (1) is excited from the exterior, preferably by vibrating systems, preferably by vibrators, to perform vibrations and/or by a rotating device is caused to rotate and/or receives a momentum or impact.
D. Method according to one of the aspects A to C, in which the force action is effected by internal drive devices, preferably,
   electrostatic comb drives or
   by drives that utilize magnetic fields of conductors through which current flows, or the travel is effected by deformations wherein at least two, in particular elastic, connections to the separated structure part (2) with different thermal expansion upon heating, different in respect to absolute value or direction and heated by current flow, preferably different based on absolute value, because of a different cross-section or different thermal dissipation loss.
E. Method according to the aspects A to D, in which the fixation or securing action of the separated part (2) after positioning or new orientation is mechanically realized by means of the structuring of simple or staggered locking catches (11, 15), preferably assisted by restoring springs, or electromechanically by microactuators, or as a result of thermal deformation of structures, which in this way at least partially engage the travel path, and wherein these structures stop at least the return movement freedom as a result of blocking structures, preferably lock bolts (17) or spring-elastically supported toothings, in particular those with different flanks.
F. Method according to one of the aspects A to E, in which by at least one measure of the group of targeted gluing, wedging, soldering of structures, or destruction of parts thereof, wherein the structures or structure parts serve for maintaining movability, wherein preferably for the destruction thermal melting of a resistor which is flowed through by current is utilized, and for any of these measures, the movability of the separated and positioned part (2) is permanently or irreversibly impaired, at least in the opposite direction to the direction (9) or to the rotational direction from where the approach of the separated parts (2, 3) has taken place.
G. Microelectromechanical converter (1) with a thickness that relative to the surface area expansion is minimal and at least one structure part that relative to a surrounding part (3) is at least partially separated, preferably secured by elastic connections, which has opposite electrodes (5) on preferably parallel extending separating groove walls (21), which preferably extend meandering or zigzag-shaped or in a winding shape or a course extending back and forth, characterized in that this converter (1)
   has an aspect ratio in the operative rest position within a section of the separating groove (20) that is in the range of 15 to 500, preferably in the range of 20 to 200, in particular has a constant value as much as possible across this section that is at least 25 times the structural depth (19) relative to the separating groove width (7), and
   has a capacitive converter sensitivity within this section whose direction (10) at least approximately is normal to the tangential surfaces of the oppositely positioned separating groove walls in the considered section with the separating groove wall width (7) and
   has means that are suitable to durably or permanently secure at least one movement of a separated structure part (2) relative a further structure part (3) in one direction (9) or rotational direction, and
   the converter for at least one further direction (10) that is independent of the direction (9) enables a movability between the structure parts (2, 3), wherein the relative position and orientation of these separated structure parts (2, 3) that are manufactured of a single piece is unequal to that which existed before or during the manufacture of the separating groove, and the remaining directions of the movability are unequal to that which existed before positioning and activation or the use of the means for fixation.
H. Microelectromechanical converter (1) according to aspect G, that
   has at least one inner drive devices of the group of electrostatic comb drives, piezo elements, drives that utilize magnetic fields of conductors through which current flows, drives as a result of deformations, as a result of different thermal expansion as a result of different shape and/or material properties, preferably in connection with current flow therethrough, preferably changes of shape of defined connections to the separated structure part (2) or as pushing elements preferably curved or spiral-shaped elements provided with lever arm whose travel between separating groove sections (20) on another side widens to a greater distance (8) so that the spacings between the electrodes (5) on the other side is reduced to the reduced spacing (7), or
   has supporting devices for external devices for force action or torque transmission, in particular thermally changing elements, magnetic elements, or special vibration-capable suspensions or torsion-capable rotational axes, or supports for targeted straight gliding or for rotary movements of separated bodies.
I. Microelectromechanical converter (1) according to one of the aspects G or H that has bending-elastic connections (6) between the structure part (2) and the surrounding part (3) which in the operating state are in tensioned deflection.
J. Microelectromechanical converter (1) according to one of the aspects G to I, in which the separated structure part (2) has limited movability in two directions (9, 10) independent from each other as a result of shaping of a structure part (2) and the surrounding part (3) relative to each other and/or bending-elastic connections (6), wherein the travel path has locking devices (11, 15) that permanently or irreversibly block the relative movement of the structure part (2) for movement in one direction (9) relative to the surrounding part (3).
K. Microelectromechanical converter (1) according to one of the aspects G to I, in which bending elastic connections (6) are arranged between the structure part (2) and the surrounding part (3) such that a relative rotation between the parts (2, 3) is enabled at a limited angle and fixation elements (11, 15), preferably in the form of locking pawls with tooth flanks enables preferably only a rotation in one rotational direction (9) as a result of asymmetric tooth flanks.
L. Microelectromechanical converter (1) according to one of the aspects G to K that comprises at least one wedge, an adhesive and/or a soldering location which serves for locking the movability of the structure parts (2, 3) relative to each other in the direction (9) or rotational direction for structure part positioning in the operative rest position.
M. Microelectromechanical converter (1) according to one of the aspects G to K that has simple or stacked locking catches (11, 15), preferably formed of springs with hooks and barbs (14), wherein at least one of the springs with hook (14) is formed on one of the separate parts (2, 3) of the structure, respectively, and wherein after hooking a degree of freedom is maintained preferably as a result of the embodiment of bending beam-type feeding of the hooks or as a result of independent spring beam support for the actuating or sensing movement or rotation, preferably in a direction (10) that is independent of the hooking direction (9) or rotational direction.
N. Microelectromechanical converter (1) according to one of the aspects G to K that comprises mechanical actuating members, preferably in the form of micro bars, electromechanical microactuators or thermally changeable structures, which introduce blocking structures, preferably sliding bolts, into the of the separated and positioned or re-oriented structure part (2) transversely to the movement paths.
O. Microelectromechanical converter (1) according to one of the aspects G to N that is at least one individual component or at least one component of an integrated circuit of the three components
   sensor for one or several of the measuring values of the group: travel, acceleration, force, vibration, speed, rotary speed, pressure and torque, or
   actuator in the form of one of the devices of the group: micromotor for linear movement, micromotor for a rotating movement, vibration generator (vibrator), micropump, micro drive, preferably for light modulators on mirror(arrays)), mechanical microswitch and relay, or
   adjustable capacitor.

What is claimed is:

1-20. (canceled)

21. A method for manufacturing microelectromechanical device (1) with high aspect ratio, comprising the steps of:
separating at least one structure part (2) of a silicon wafer or a semiconductor component with a thickness that is minimal in relation to the surface expansion by chemical and/or physical material removal with technology-related aspect ratio relative to a surrounding part (3) or a further structure part (3) by producing separating grooves (20) and forming at least two separating groove wall sections (21), that are oppositely positioned and are preferably embodied as capacitive electrodes (5) and that each have structures with projections from a main expansion direction (9) of the separating groove wall section surfaces (21), with a defined spacing (4) of structures of the structure part (2) relative to those of the surrounding part (3) or the further structure part (3), wherein bending-elastic connections (6) may remain between the structure part (2) and its surrounding material,
subsequently reducing the spacing (4 toward 7) between the at least two oppositely positioned wall sections (21) of the separating grooves (20) and preferably embodied as capacitive electrodes (5) by mechanical relative lateral position change of the separated structure part (2) relative to the surrounding part (3) or one of the further structure parts (3) of a semi-conductor surface by inner and/or outer devices that exert or transmit a force action or a torque on at least one of the parts (2, 3) separated from each other,
after reducing the spacing (4 toward 7) in a defined separating groove section (20), securing at least one separated structure part (2) permanently or irreversibly by a device (11, 15) against an increase of a spacing (7′ toward 4′) in the direction opposite to the realized direction (9) of the position change of the separating groove wall sections that have approached each other.

22. The method according to claim 21, wherein the projections of the oppositely positioned separating groove wall sections (21) immediately after producing the separating grooves (20) are positioned opposite each other in staggered arrangement and, in the step of reducing the spacing (4 toward 7) by the relative lateral position change of the oppositely positioned separating groove wall sections (21), projections of the oppositely positioned separating groove wall sections are transferred from a staggered position, i.e., an asymmetric position, into an oppositely positioned, i.e., mirror-symmetrical, position (7, 8).

23. The method according to claim 21, wherein spacings (4) of oppositely positioned wall sections of the separating grooves (20), which are arranged between the projections, respectively, are changed to greater spacings (8) in the step of reducing the spacing (4 toward 7) between the projections.

24. The method according to claim 23, in which for improving damping properties of microelectromechanical devices (1) a defined ratio is selected of surface areas of the wall sections, arranged between the projections of the separating grooves (20), relative to the surface areas of the projections.

25. The method according to claim 21, wherein the at least two oppositely positioned separating groove wall sections (21) are embodied as capacitive electrodes (5) and in the step of securing the at least one structure part (2) is not secured against a movability for changing the spacing (7, 8) in a direction (10) that is different from, preferably orthogonal to, the direction (9) of position change, wherein a part (13) of the device is embodied for enabling an appropriate independent degree of freedom for movement.

26. The method according to claim 21, wherein in the step of separating material removal is done by an etching process, preferably a dry etching process, in particular a reactive ion etching process, especially preferred a reactive ion depth etching process (deep reactive ionic etching, DRIE).

27. The method according to claim 21, in which the force action or torque generation for relative positional change is caused as a result of:
an external gravitation field, preferably by the force action of the earth's gravitation on the mass of the at least one separated structure part (2) with fixation of the surrounding part (3) or, in reverse, on the mass of the surrounding part (3) with fixation of the at least one structure part (2), or
an external electrical field, preferably generated by a highly electrically charged body which is positioned in the direction of that side of the at least one structure part (2) in which the at least one structure part (2) is to be moved translatorily relative to the surrounding part (3) to the nominal position, or by which a torque as a result of a suitably arranged elastic or torsion-capable suspension of the at least one structure part (2) is generated whereby the latter and possible further structure parts are rotated into the nominal orientation position, or
an external magnetic field, preferably by the interaction of a field as a result of current flow through at least one of the parts (2, 3) separated from each other and of the magnetic field of an external permanent magnet or an external electromagnet,
a temperature change of the environment which causes deformations as a result of different heat expansions or cold contractions of an appropriate configuration of the bending-elastic connections (6), or
a length change by electrostriction or magnetostriction of structure connecting parts, especially of the bending elastic connections (6).

28. The method according to claim 21, in which the force action or the torque causes the relative movements of the at least one separated structure part (2) relative to the remaining structure by utilizing vibration and resonance, wherein the microelectromechanical device (1) is excited from the exterior, preferably by vibrating systems, preferably by vibrators, to perform vibrations which cause excitation of resonance vibrations of at least one separated structure part (2), in particular by the bending-elastic connections (6).

29. The method according to claim 21, in which:
the force action is effected by internal drive devices, preferably by electrostatic comb drives or by drives that utilize magnetic fields of conductors through which current flows, or
the travel is effected by deformations wherein at least two, in particular elastic, connections to the separated structure part (2) with thermal expansion differing in respect to absolute value or direction upon heating are heated by current flow, wherein the thermal expansion is preferably different based on absolute value because of a different cross-section or different thermal dissipation loss, or
the travel is effected by deformations of separate structures that upon current flow as a result of thermally caused deformation push away the separated structure part (2).

30. The method according to claim 21, wherein securing of the separated part (2) after positioning is mechanically realized by structuring of locking catches (11, 15), preferably assisted by restoring springs, or electromechanically by microactuators, or as a result of thermal deformation of structures, which thereby at least partially engage the travel path, and wherein the structures stop at least the return movement freedom by blocking structures, preferably lock bolts (17) or spring-elastically supported toothings, in particular those with different flanks.

31. The method according to claim 21, further comprising at least one additional step of the group: targeted gluing, wedging, soldering of structures, or destroying of parts thereof, wherein the structures or structure parts serve for maintaining movability, wherein preferably for destroying thermal melting of a resistor which is flowed through by current is utilized, and for any of these additional steps, the movability of the separated and positioned part (2) is permanently or irreversibly impaired, at least in the opposite direction to the direction (9) or to the rotational direction from where the approach of the separated parts (2, 3) has taken place.

32. A method for manufacturing microelectromechanical devices (1) with high aspect ratio, comprising the steps of:
separating at least one structure part (2) of a silicon wafer or a semiconductor component with a thickness that is minimal in relation to the surface expansion by chemical and/or physical material removal with technology-related aspect ratio relative to a surrounding part (3) or a further structure part (3) by producing separating grooves (20) and forming at least two separating groove wall sections (21) that are oppositely positioned and are preferably embodied as capacitive electrodes (5) that each have stair-like structures and a defined spacing (4) of structures of the structure part (2) relative to those of the surrounding part (3) or the further structure part (3), wherein bending-elastic connections (6) may remain between the structure part (2) and its surrounding material,
subsequently reducing the spacing (4 toward 7) of the stair-like structures between the at least two oppositely positioned wall sections (21) of the separating grooves (20) produced by removal and preferably embodied as capacitive electrodes (5) by mechanical relative position change in one direction (9) of the separated structure part (2) relative to the surrounding part (3) or one of the further structure parts (3) of a semi-conductor surface by inner and/or outer devices that exert or transmit a force action or a torque on at least one of the parts (2, 3) separated from each other,
after approach (4 toward 7) of the stair-like structures in a defined separating groove section (20), securing at least one separated structure part (2) permanently or irreversibly by a device (11, 15) against an increase of a spacing (7′ toward 4′) in the direction opposite to the realized direction (9) of the position change of the separating groove wall sections that have approached each other.

33. The method according to claim 32, wherein the stair-like structures of the oppositely positioned separating groove wall sections (21) immediately after producing the separating grooves (20) do not mesh with each other and in the step of reducing the spacing (4 toward 7) are brought into stair-like engagement with each other.

34. The method according to claim 32, wherein the at least two oppositely positioned separating groove wall sections (21) are embodied as capacitive electrodes (5) and in the step of securing the at least one structure part (2) is not secured against a movability for changing the spacing (7, 8) in a direction (10) that is different from, preferably orthogonal to, the direction (9) of position change, wherein a part (13) of the device is embodied for enabling an appropriate independent degree of freedom for movement.

35. The method according to claim 32, in the step of separating material removal is done by an etching process, preferably a dry etching process, in particular a reactive ion etching process, especially preferred a reactive ion depth etching process (deep reactive ionic etching, DRIE) is employed.

36. The method according to claim 32, in which the force action or torque generation for relative positional change is caused as a result of:
an external gravitation field, preferably by the force action of the earth's gravitation on the mass of the at least one separated structure part (2) with fixation of the surrounding part (3) or, in reverse, on the mass of the surrounding part (3) with fixation of the at least one structure part (2), or
an external electrical field, preferably generated by a highly electrically charged body which is positioned in the direction of that side of the at least one structure part (2) in which the at least one structure part (2) is to be moved translatorily relative to the surrounding part (3) to the nominal position, or by which a torque as a result of a suitably arranged elastic or torsion-capable suspension of the at least one structure part (2) is generated whereby the latter and possible further structure parts are rotated into the nominal orientation position, or
an external magnetic field, preferably by the interaction of a field as a result of current flow through at least one of the parts (2, 3) separated from each other and the magnetic field of an external permanent magnet or an external electromagnet,
a temperature change of the environment which causes deformations as a result of different heat expansions or cold contractions of an appropriate configuration of the bending-elastic connections (6), or
a length change by electrostriction or magnetostriction of structure connecting parts, especially of the bending elastic connections (6).

37. The method according to claim 32, in which the force action or the torque causes the relative movements of the at least one separated structure part (2) relative to the remaining structure by utilizing vibration and resonance, wherein the microelectromechanical device (1) is excited from the exterior, preferably by vibrating systems, preferably by vibrators, to perform vibrations which cause excitation of resonance vibrations of at least one separated structure part (2), in particular by the bending-elastic connections (6).

38. The method according to claim 32, in which:
the force action is effected by internal drive devices, preferably by electrostatic comb drives or by drives that utilize magnetic fields of conductors through which current flows, or
the travel is effected by deformations wherein at least two, in particular elastic, connections to the separated structure part (2) with thermal expansion differing in respect to absolute value or direction upon heating are heated by current flow, wherein the thermal expansion is preferably different based on absolute value because of a different cross-section or different thermal dissipation loss, or
the travel is effected by deformations of separate structures that upon current flow as a result of thermally caused deformation push away the separated structure part (2).

39. The method according to claim 32, wherein securing of the separated part (2) after positioning is mechanically realized by structuring of locking catches (11, 15), preferably assisted by restoring springs, or electromechanically by microactuators, or as a result of thermal deformation of structures, which thereby at least partially engage the travel path, and wherein the structures stop at least the return movement freedom by blocking structures, preferably lock bolts (17) or spring-elastically supported toothings, in particular those with different flanks.

40. The method according to claim 32, further comprising at least one additional step of the group: targeted gluing, wedging, soldering of structures, or destroying of parts thereof, wherein the structures or structure parts serve for maintaining movability, wherein preferably for destroying thermal melting of a resistor which is flowed through by current is utilized, and for any of these additional steps, the movability of the separated and positioned part (2) is permanently or irreversibly impaired, at least in the opposite direction to the direction (9) or to the rotational direction from where the approach of the separated parts (2, 3) has taken place.

41. A microelectromechanical converter (1) with at least one structure part (2) that relative to a surrounding part (3) or a further structure part (3) is at least partially separated by separating grooves (20), preferably secured by elastic connections, and electrodes (5) on oppositely positioned, preferably meandering or zigzag-shaped or of a winding shape or of a course extending back and forth, preferably parallel, separating groove walls (21) that section-wise are arranged between at least two such separated parts (2, 3), wherein this converter (1)
has an aspect ratio in the operative rest position within a section of the separating groove (20) that is in a range of 15 to 500, preferably in a range of 20 to 200, in particular has a constant value as much as possible preferably across this section, the value being at least 25 times the structure depth (19) relative to the separating groove width (7), and
has a device (11, 15) which secures or fixes the at least one separated structure part (2) relative to a surrounding part (3) or a further structure part (3) in an operative rest position, and
in said section of the separating groove (20) with the afore mentioned aspect ratio hast at least two oppositely positioned separating groove wall sections (21) that each have
(a) structures with projections from a lateral main expansion direction (9) of the separating groove wall section surfaces (21) or
(b) stair-like structures.

42. Microelectromechanical converter (1) according to claim 41 that has
at least one inner drive devices of the group of: electrostatic comb drives, piezo elements, drives that utilize magnetic fields of conductors through which current flows, drives as a result of deformations, as a result of different thermal expansion as a result of different shape and/or material properties, preferably at current flow therethrough, preferably changes of shape of defined connections to the separated structure part (2), or, as pushing elements, preferably curved or spiral-shaped elements provided with lever arm, whose travel between separating groove sections (20) on another side widens to a greater distance (8) so that the spacings between the electrodes (5) on the other side are reduced to the reduced spacing (7), or
supporting devices for external devices for force action or torque transmission, in particular thermally changing elements, magnetic elements, or special vibration-capable suspensions or torsion-capable rotational axes, or supports for targeted straight gliding or for rotary movements of separated bodies.

43. Microelectromechanical converter (1) according to claim 41 that has bending-elastic connections (6) between the structure part (2) and the surrounding part (3) which in the operating state are deflected, preferably with a defined spring tension.

44. Microelectromechanical converter (1) according to claim 41, in which the separated structure part (2) has dimensionally limited movability, preferably in two directions (9, 10) independent from each other, as a result of shaping of a structure part (2) and the surrounding part (3) relative to each other and/or bending-elastic connections (6), wherein the travel path, at least relative to the movement in one direction (9), has process-related locking devices (11, 15) that permanently or irreversibly block the relative movement of the structure part (2) relative to the surrounding part (3).

45. Microelectromechanical converter (1) according to claims 41, in which bending elastic connections (6) are arranged between the structure part (2) and the surrounding part (3) such that a relative rotation between the parts (2, 3) is enabled at a limited angle and fixation elements (11, 15), preferably in the form of locking pawls with tooth flanks, enables preferably only a rotation in one rotational direction (9) as a result of asymmetric tooth flanks.

46. Microelectromechanical converter (1) according to claim 41 that has locking catches (11, 15), preferably formed of springs with hooks and barbs (14), wherein at least one of the springs with hook (14) is formed on one of the separate parts (2, 3) of the structure, respectively, and wherein after hooking a degree of freedom is maintained for the actuating or sensing movement or rotation, preferably in a direction (10) or rotational direction independent of the hooking direction (9).

47. Microelectromechanical converter (1) according to claim 41 that comprises mechanical actuating members, preferably in the form of micro bars, electromechanical microactuators or thermally changeable structures, which introduce blocking structures, preferably sliding bolts, into the of the separated and positioned or re-oriented structure part (2) transversely to the movement paths.

48. Microelectromechanical converter (1) according to claim 41 that comprises at least one wedge, an adhesive and/or a soldering location, which serves for locking the movability of the structure parts (2, 3) relative to each other in the direction (9) or rotational direction for positioning of the structure part in the operative rest position.

49. Microelectromechanical converter (1) according to claim 41 that is
a sensor for travel, acceleration, force, vibration, speed, rotary speed, pressure or torque,
an actuator in the form of a micromotor for linear or rotating movement, of a vibration generator (vibrator), of a micropump, of a microdrive, preferably for light modulators on mirror (arrays)), of a mechanical microswitch or of a relay,
an adjustable capacitor,
a component of an integrated microelectronic circuit.
